(19) United States
(12) Patent Application Publication
(10) Pub. No.: US 2008/0150597 A1
(43) Pub. Date: Jun. 26, 2008

(54) APPARATUS AND METHODS FOR CONTROLLING DELAY USING A DELAY UNIT AND A PHASE LOCKED LOOP

(75) Inventors: Wei Hu, Yongin-si (KR); Phil-Jae Jeon, Osan-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/962,429

(22) Filed: Dec. 21, 2007

(30) Foreign Application Priority Data
Dec. 22, 2006 (KR) 10-2006-0132768

(51) Int. Cl. H03L 7/06

(52) U.S. Cl. 327/158

(57) ABSTRACT

An apparatus for controlling a delay includes a phase locked loop and a delay unit. The phase locked loop generates an oscillation signal having a frequency substantially identical to that of a reference signal. The delay unit includes a delay cell block that outputs delayed signals by delaying the reference signal sequentially by a uniform delay interval. The delay unit controls the delay interval based on a frequency/phase difference between a first input signal and a second input signal of the phase locked loop, and outputs one of the delayed signals as a delayed reference signal. Related methods are also described.

### CROSS-REFERENCE TO RELATED APPLICATION

This application claims the benefit under 35 USC §119 of Korean Patent Application No. 10-2006-0132768, filed on Dec. 22, 2006, the disclosure of which is hereby incorporated herein by reference in its entirety as if set forth fully herein.

### FIELD OF THE INVENTION

The present invention relates to delay control apparatus/methods in integrated circuit devices, and more particularly to apparatus and methods for controlling a delay of a reference signal.

### BACKGROUND OF THE INVENTION

Integrated circuit devices, such as memory devices, are widely used in many consumer, commercial and other applications. Synchronous memory devices such as synchronous dynamic random access memory (SDRAM) devices are configured to operate in synchronization with a clock signal having a high frequency to allow increased operating speed.

Particularly, a double data rate (DDR) SDRAM device can further increase the operating speed by using both a rising edge and a falling edge of the clock signal. Hereinafter, an operation of a DDR SDRAM device is described.

FIG. 1 is a timing diagram illustrating a writing operation of a DDR SDRAM device, and FIG. 2 is a timing diagram illustrating a reading operation of a DDR SDRAM device.

Referring to FIG. 1, a memory controller transmits a data strobe signal DQS and data DQ to a DDR SDRAM device. It is desirable for rising edges and falling edges of the data strobe signal DQS to be arranged in the center of the data DQ so that errors in writing operation may be reduced or prevented. Therefore, the memory controller transmits the data DQ and the data strobe signal DQS arranged in the center of the data DQ.

Referring to FIG. 2, a DDR SDRAM device transmits a data strobe signal DQS and data DQ to a memory controller, and the data DQ is arranged at rising edges and falling edges of the data strobe signal DQS. When the memory controller receives the data strobe signal DQS and the data DQ, a skew between the data strobe signal DQS and the data DQ may be generated according to a length of wiring and/or characteristics of input and/or output buffers.

In order to decrease an error due to skew when receiving the data strobe signal DQS and the data DQ, it may be desirable for the memory controller to arrange the rising edges and the falling edges of the data strobe signal DQS in the center of the data DQ by delaying the strobe signal DQS. A delay control apparatus/method may be used to provide the delay.

### SUMMARY OF THE INVENTION

Some exemplary (i.e., illustrative) embodiments of the present invention provide apparatus for controlling a delay of a reference signal to output a delayed reference signal.

Some exemplary embodiments of the present invention provide methods of controlling a delay of a reference signal to output a delayed reference signal.

In some exemplary embodiments of the present invention, an apparatus for controlling a delay includes a phase locked loop and a delay unit. The phase locked loop generates an oscillation signal having a frequency substantially identical to that of a reference signal. The delay unit includes a delay cell block configured to output delayed signals by delaying the reference signal sequentially by a uniform delay interval. The delay unit controls the delay interval based on a frequency/phase difference between a first input signal and a second input signal of the phase locked loop and outputs one of the delayed signals as a delayed reference signal.

The delay unit may decrease the delay interval when the frequency/phase of the first input signal is higher than that of the second input signal, and may increase the delay interval when the frequency/phase of the first input signal is lower than that of the second input signal.

The delay unit may output the one of the delayed signals as the delayed reference signal based on a selection signal that is provided externally and/or set in advance.

The phase locked loop may generate a control voltage based on the frequency/phase difference between the first input signal and the second input signal, convert the control voltage into a bias current, generate the oscillation signal based on the bias current, and generate the second input signal by dividing the oscillation signal.

The phase locked loop may increase the control voltage when the frequency/phase of the first input signal is higher than that of the second input signal, may increase the bias current according to the increased control voltage, and may increase a frequency of the oscillation signal based on the increased bias current.

The phase locked loop may decrease the control voltage when the frequency/phase of the first input signal is lower than that of the second input signal, may decrease the bias current according to the decreased control voltage, and may decrease a frequency of the oscillation signal based on the decreased bias current.

The phase locked loop may include a ring oscillator controlling the frequency of the oscillation signal based on the bias current that may be increased when the frequency/phase of the first input signal is higher than that of the second input signal or that may be decreased when the frequency/phase of the first input signal is lower than that of the second input signal.

The ring oscillator may increase the frequency of the oscillation signal when the bias current is increased, and may decrease the frequency of the oscillation signal when the bias current is decreased.

The delay unit may control the delay interval based on the converted bias current.

The delay unit may increase the frequency of the delayed signals by decreasing the delay interval when the bias current is increased, and may decrease the frequency of the delayed signals by increasing the delay interval when the bias current is decreased.

The delay unit may further include a single-to-differential converter and a multiplexer. The single-to-differential converter may convert the reference signal into differential signals. The multiplexer may select the one of the delayed signals as the delayed reference signal based on a selection signal that is provided externally and/or set in advance. The delay cell block may include delay cells, and each of the delay cells may control the delay interval based on the increased or decreased bias current.

Each of the delay cells may include a first p-channel transistor, such as a p-channel metal oxide semiconductor (PMOS) transistor, a second PMOS, a first n-channel transistor, such as an n-channel metal oxide semiconductor (NMOS) transistor, a second NMOS, and a third NMOS. The first PMOS may mirror a first bias current, and a source of the first PMOS may receive a first reference voltage. The second PMOS may mirror the first bias current, and a source of the second PMOS may receive the first reference voltage. The first NMOS may have a gate receiving a first signal of the differential signals and a drain coupled to a drain of the first PMOS. The second NMOS may have a gate receiving a second signal of the differential signals and a drain coupled to a drain of the second PMOS. The third NMOS may mirror a second bias current, and may have a source receiving a second reference voltage and a drain coupled to sources of the first NMOS and the second NMOS.

The delay unit may generate the bias current based on a control voltage generated from the phase locked loop, and may control the delay interval based on the bias current.

The delay unit may increase the frequency of the reference signal by decreasing the delay interval when the bias current is increased, and may decrease the frequency of the reference signal by increasing the delay interval when the bias current is decreased.

The delay unit may control the delay interval based on a control voltage generated from the phase locked loop.

The delay unit may increase the frequency of the delayed signals by decreasing the delay interval when the control voltage is increased, and may decrease the frequency of the delayed signals by increasing the delay interval when the control voltage is decreased.

The reference signal may correspond to a data strobe signal of a dynamic random access memory (DRAM).

Apparatus for controlling a delay according to other embodiments of the invention include a phase locked loop and a delay unit configured to output a delayed reference signal in response to a reference signal applied thereto. The delay unit is powered by a power supply and is biased by a bias current/voltage that is generated from the phase locked loop. In some embodiments, the delay unit includes a plurality of serially connected delay stages, a respective one of which is powered by the power supply and is biased by the bias current/voltage that is generated from the phase locked loop.

In methods of controlling a delay according to some exemplary embodiments of the present invention, delayed signals are generated by delaying a reference signal sequentially by a uniform delay interval. The delay interval is controlled based on a frequency/phase difference between a first input signal and a second input signal of a phase locked loop that outputs an oscillation signal having a frequency substantially identical to that of the reference signal. One of the delayed signals is output as a delayed reference signal.

The delay interval may be controlled by decreasing the delay interval when the frequency/phase of the first input signal is higher than that of the second input signal, and by increasing the delay interval when the frequency/phase of the first input signal is lower than that of the second input signal.

The one of the delayed signals may be output as the delayed reference signal based on a selection signal that is provided externally and/or set in advance.

The delay interval may be controlled by generating a control voltage based on the frequency/phase difference between the first input signal and the second input signal, by converting the control voltage into a bias current, and by controlling the delay interval based on the converted bias current.

The delay interval may be controlled based on the converted bias current by increasing the frequency of the delayed signals by decreasing the delay interval when the bias current is increased and by decreasing the frequency of the delayed signals by increasing the delay interval when the bias current is decreased.

According to other method embodiments, a delay is controlled by biasing a delay unit, which is configured to output a delayed reference signal in response to a reference signal applied thereto, and is powered from a power supply. The delay unit is biased with a bias current/voltage that is generated from a phase locked loop. In some embodiments, bias current/voltage is generated in response to a frequency/phase difference in the phase locked loop.

### BRIEF DESCRIPTION OF THE DRAWINGS

FIG. 1 is a timing diagram illustrating a writing operation of a conventional DDR SDRAM device.

FIG. 2 is a timing diagram illustrating a reading operation of a conventional DDR SDRAM device.

FIG. 3 is a block diagram illustrating apparatus/methods of controlling a delay according to some embodiments of the present invention.

FIG. 4 is a circuit diagram illustrating a delay cell of FIG. 3 according to some embodiments of the present invention.

FIG. 5 is a timing diagram illustrating controlling an apparatus/method of FIG. 3.

FIG. 6 through FIG. 8 are block diagrams illustrating apparatus/methods for controlling a delay according to other embodiments of the present invention.

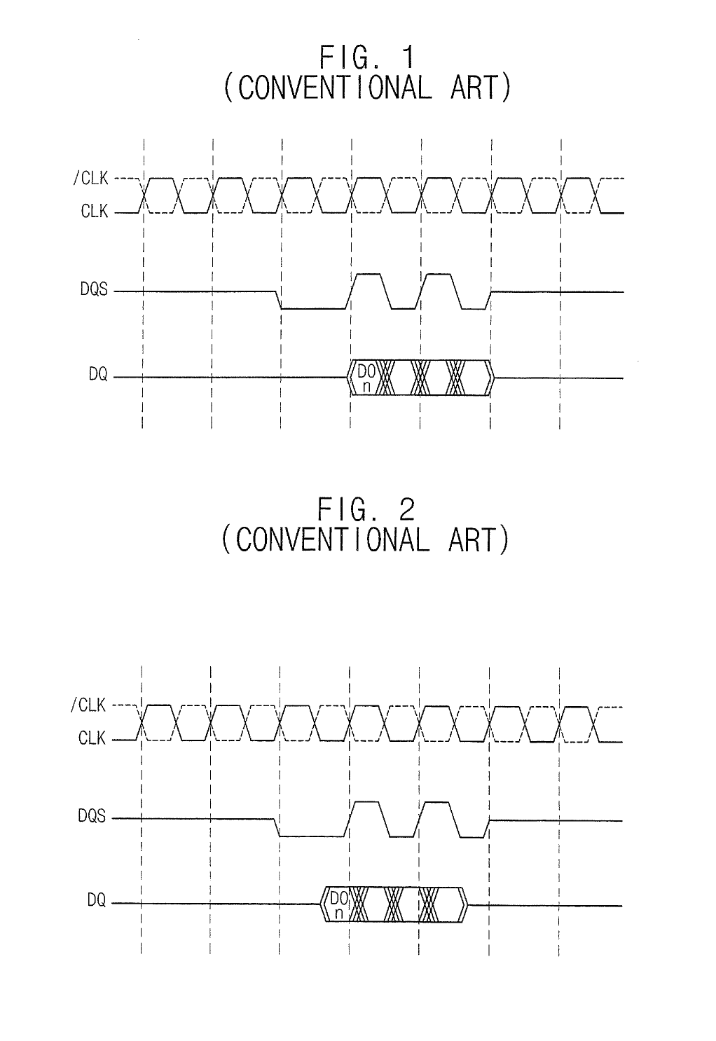

### DESCRIPTION OF THE EMBODIMENTS

Embodiments of the present invention now will be described more fully with reference to the accompanying drawings, in which embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected”, “coupled” or “responsive” to another element (and variants thereof, it can be directly connected, coupled or responsive to the other element or intervening elements may be present. In contrast, when an element is referred to as being “directly connected”, “directly coupled” or “directly responsive” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including” (and variants thereof), when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

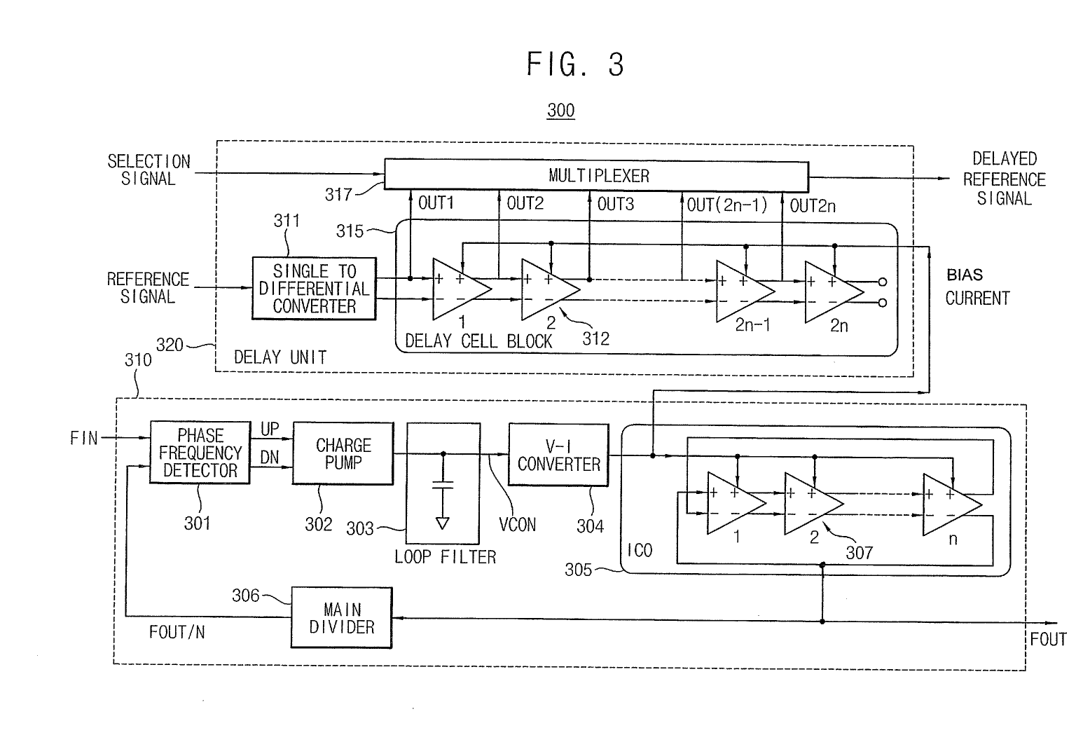

FIG. 3 is a block diagram illustrating apparatus/methods for controlling a delay according to some embodiments of the present invention.

Referring to FIG. 3, an apparatus/method 300 for controlling a delay includes a phase locked loop (PLL) 310, and a delay unit 320.

The PLL 310 generates an output signal FOUT or an oscillation signal having a frequency substantially identical to that of a reference signal. For example, a reference signal may correspond to a data strobe signal DQS used in a double data rate synchronous dynamic random access memory (DDR SDRAM) device.

The delay unit 320 includes a delay cell block 315 generating delayed signals by sequentially delaying the reference signal by a uniform delay interval within a period of the reference signal. The delay unit 320 controls the delay interval of the delay cell block 315 based on a bias current provided by the PLL 310, where the bias current is determined based on a frequency/phase difference between a first input signal and a second input signal of the PLL 310. The delay unit 320 outputs one of the delayed signals as a delayed reference signal at a specific time. For example, the delayed reference signal may correspond to a data strobe signal DQS arranged in center of the data DQ in the DDR SDRAM device.

That is, the delay unit 320 decreases the delay interval of the delay cell block 315 when the frequency/phase of the first input signal is higher than that of the second input signal, and increases the delay interval of the delay cell block 315 when the frequency/phase of the first input signal is lower than that of the second input signal.

The delay unit 320 may output one of the delayed signals of the delay cell block 315 as the delayed reference signal based on a selection signal. The selection signal may be provided from an external device such as a memory controller and/or may be set in advance (e.g., set in a register).

FIG. 3 may also be regarded as providing an apparatus for controlling a delay that includes a phase locked loop 310 and a delay unit 320 configured to output a delayed reference signal in response to a reference signal applied thereto. The delay unit 320 is powered by a power supply and is biased by a bias current/voltage that is generated from the phase locked loop 310. In method embodiments, a delay unit 320 is biased with a bias voltage/current that is generated from the phase locked loop 310. The delay unit 320 is configured to output a delayed reference signal in response to a reference signal applied thereto and is powered from a power supply. The bias current/voltage is generated in response to a frequency/phase difference in the phase locked loop 310.

The phase locked loop 310 may include a phase/frequency detector 301, a charge pump 302, a loop filter 303, a voltage-current (V-I) converter 304, a ring oscillator 305, and a divider 306.

The phase/frequency detector 301 generates a first control signal UP and a second control signal DN by comparing a frequency/phase between the first input signal FIN and the second input signal FOUT/N. As illustrated in FIG. 3, the second input signal FOUT/N may be a feedback signal provided by a divider 306 for dividing the output signal FOUT. For example, the phase/frequency detector 301 may generate the first control signal UP when a phase/frequency of the first input signal FIN is higher than that of the second input clock FOUT/N, and the phase/frequency detector 301 may generate the second control signal DN when the phase/frequency of the first input signal FIN is lower than that of the second input clock FOUT/N.

The charge pump 302 controls an amount of a current to or from the loop filter 303 based on the first control signal UP and the second control signal DN. For example, when the charge pump 302 receives the first control signal UP from the phase/frequency detector 301, the charge pump 302 may charge the loop filter 303. When the charge pump 302 receives the second control signal DN from the phase/frequency detector 301, the charge pump 302 may discharge the loop filter 303.

The loop filter 303 generates the control voltage VCON based on the charging/discharging current controlled by the charge pump 302. For example, when the charging current is provided by the charge pump 302, the loop filter 303 may increase the control voltage VCON. When the discharging current is provided by the charge pump 302, the loop filter 303 may decrease the control voltage VCON.

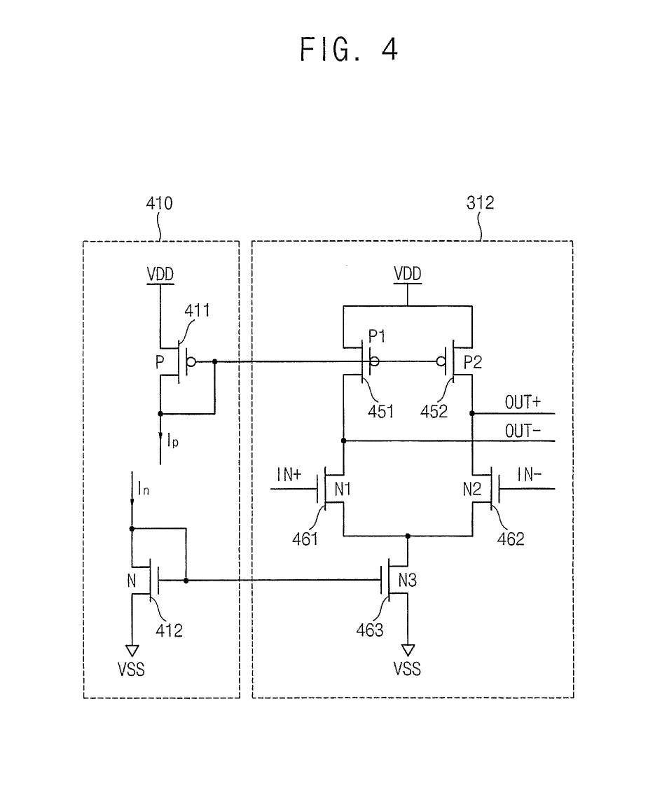

The voltage-current converter 304 generates a bias current based on the control voltage VCON provided from the loop filter 303. For example, the bias current may correspond to a single bias current or may correspond to a plurality of the bias currents (e.g., Iₚ and Iₙ illustrated in FIG. 4) generated based on the single bias current.

The ring oscillator 305 may include a plurality of differential inverters 307 and/or an odd number of inverters, generates an output signal FOUT based on the bias current outputted from the voltage-current converter 304. For example, the ring oscillator 305 may control a frequency of the output signal FOUT based on the bias current. The bias current is increased when the frequency/phase of the first input signal FIN is higher than that of the second input signal FOUT/N and is decreased when the frequency/phase of the first input signal FIN is lower than that of the second input signal FOUT/N.

That is, the ring oscillator 305 increases the frequency of the output signal FOUT when the bias current is increased, and decreases the frequency of the output signal FOUT when the bias current is decreased.

The delay unit 320 includes a single-to-differential converter 311, the delay cell block 315, and a multiplexer 317.

The single-to-differential converter 311 converts the reference signal, which is a single-ended signal, into differential signals, and delay cells 312 included in the delay cell block 315 receive the differential signals. However, when the delay cells 312 are embodied by an inverter receiving a single-ended signal, the delay unit 320 can directly provide the reference signal and the single-to-differential converter 311 may be omitted.

The delay cell block 315 may include the delay cells 312, and each of the delay cells 312 delays a received signal by the delay interval based on the increased or decreased bias current. For example, the delay cell block 315 may increase the frequency of the reference signal by decreasing the delay interval when the bias current is increased, and may decrease the frequency of the reference signal by increasing the delay interval when the bias current is decreased.

The multiplexer 317 selects one of the delayed signals as the delayed reference signal based on the selection signal. As described above, the selection signal may be provided from an external device such as a memory controller and/or may be set in advance (e.g., set in a register).

Hereinafter, an entire operation of an apparatus/method 300 of controlling a delay is described.

The PLL 310 converts the control voltage VCON generated based on the frequency/phase difference between the first input signal FIN and the second input signal FOUT/N into the bias current and generates the output signal FOUT based on the bias current. The second input signal FOUT/N is generated by dividing the output signal FOUT.

For example, the PLL 310 may increase the control voltage VCON when the frequency/phase of the first input signal FIN is higher than that of the second input signal FOUT/N, may increase the bias current according to the increased control voltage VCON, and may increase the frequency of the output signal FOUT based on the increased bias current. Also, the PLL 310 may decrease the control voltage VCON when the frequency/phase of the first input signal FIN is lower than that of the second input signal FOUT/N, may decrease the bias current according to the decreased control voltage VCON, and may decrease the frequency of the output signal FOUT based on the decreased bias current.

The delay unit 320 controls the delay interval based on the bias current. For example, the delay unit 320 may increase the frequency of the reference signal by decreasing the delay interval when the bias current is increased, and may decrease the frequency of the reference signal by increasing the delay interval when the bias current is decreased.

According to other method embodiments, the delay unit 320 is biased with a bias current/voltage that is generated from the phase locked loop 310. The delay unit 320 is configured to output a delayed reference signal in response to a reference signal applied thereto, and is powered from a power supply. The bias current/voltage may be generated in response to a frequency/phase difference in the phase locked loop 310.

FIG. 4 is a circuit diagram illustrating a delay cell of FIG. 3.

Referring to FIG. 4, the delay cell 312 may include a first p-channel transistor, such as a p-channel metal oxide semiconductor (PMOS) transistor 451, a second PMOS 452, a first n-channel transistor, such as an n-channel metal oxide semiconductor (NMOS) transistor 461, a second NMOS 462, and a third NMOS 463. The delay cell is powered by a power supply VDD. It will also be understood that although power supply connections are not illustrated in the other block diagrams for simplification, the electrical circuits of these block diagrams include a power supply connection for powering the circuits.

The differential inverter 307 included in the ring oscillator 305 in FIG. 3 may have the same configuration as the delay cell 312 illustrated in FIG. 4. A current supply unit 410 may be included in the voltage-current converter 304, which is well known to those skilled in the art. The current supply unit 410 provides the bias current generated by the voltage-current converter 304 to the first PMOS 451, the second PMOS 452, and the third NMOS 463 of the delay cell 312, respectively.

Even though a plurality of the bias currents Iₚ and Iₙ are illustrated in FIG. 4 for convenience of description, the bias currents may be the same.

The first PMOS 451 forms a current mirror with a PMOS 411 in the voltage-current converter 304 and provides a mirrored current of a first bias current Iₚ to flow through the first PMOS 451. The source of the first PMOS 451 receives a first reference voltage. The second PMOS 452 forms a current mirror with the PMOS 411 in the voltage-current converter 304 and provides a mirrored current of the first bias current Iₚ to flow through the second PMOS 452. The source of the second PMOS 452 receives the first reference voltage. The reference voltage may be the power supply voltage VDD as illustrated in FIG. 4.

The first NMOS 461 has a gate receiving one signal IN+ of differential signals and a drain coupled to the drain of the first PMOS 451. The second NMOS 462 has a gate receiving the other signal IN− of the differential signals and a drain coupled to the drain of the second PMOS 452. The third NMOS 463 forms a current mirror with a PMOS 412 in the voltage-current converter 304 for mirroring a second bias current Iₙ. The third NMOS 463 has a source receiving a second reference voltage and a drain commonly coupled to sources of the first NMOS 461 and the second NMOS 462. The second reference voltage may be a ground voltage VSS as illustrated in FIG. 4. As such, the delay cell 312 controls the delay interval based on the bias currents Iₚ and Iₙ.

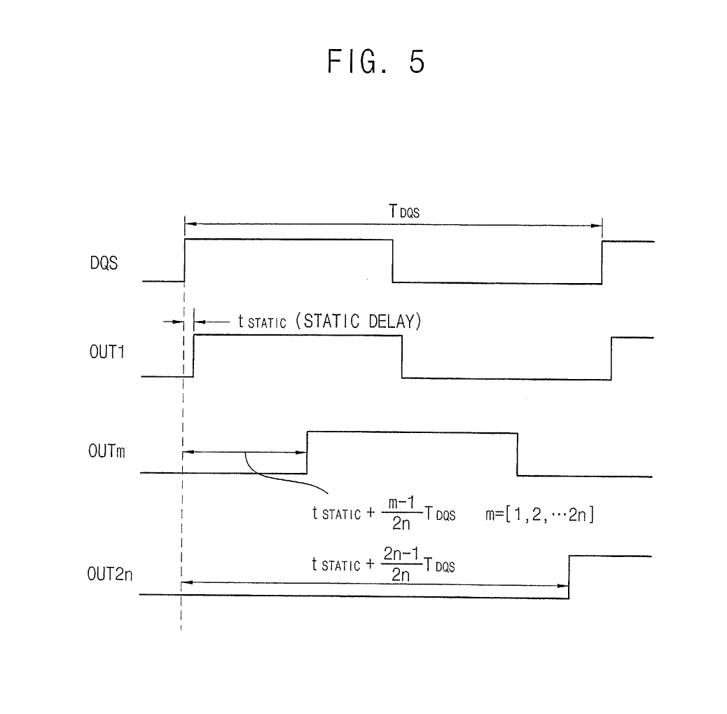

FIG. 5 is a timing diagram illustrating a controlling process of the apparatus of FIG. 3.

In FIG. 5, it is assumed that a period of the reference signal is T_{DQS}, and the number (e.g., 2N) of the delay cell 312 is double the number (e.g., N) of the differential inverters 307 included in the ring oscillator 305.

A delay of the m-th delay cell included in the delay cells 312 may correspond to a sum of a static delay t_{static} and a delay from a first delay cell to a (m-1)-th delay cell. For example, the static delay t_{static} may correspond to a delay by the single-to-differential converter 311.

Therefore, apparatus/methods 300 of controlling a delay may control the delay time of the reference signal for outputting the reference signal at a specific time that may be required in a system.

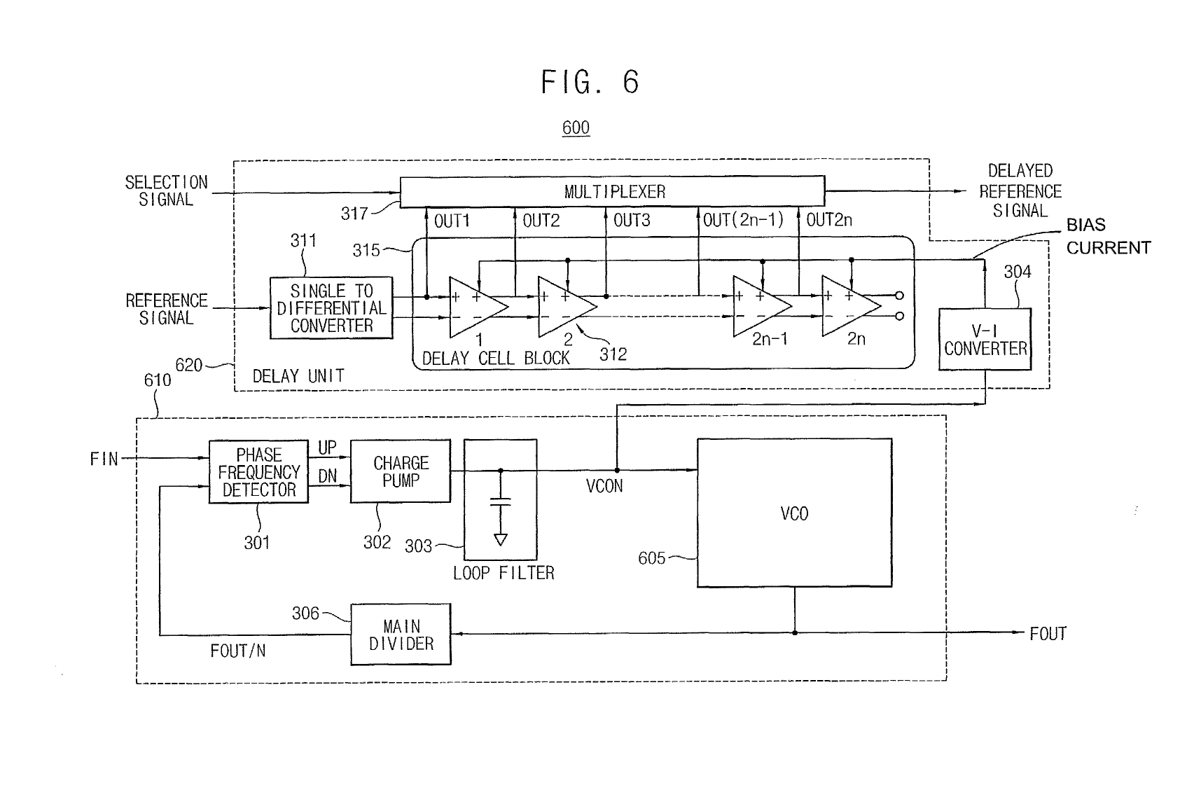

FIG. 6 through FIG. 8 are block diagrams illustrating apparatus/methods of controlling a delay according to other example embodiments of the present invention.

In apparatus/methods 600 of controlling a delay in FIG. 6, a PLL 610 uses a voltage controlled oscillator (VCO) 605 instead of the ring oscillator 305 illustrated in FIG. 3.

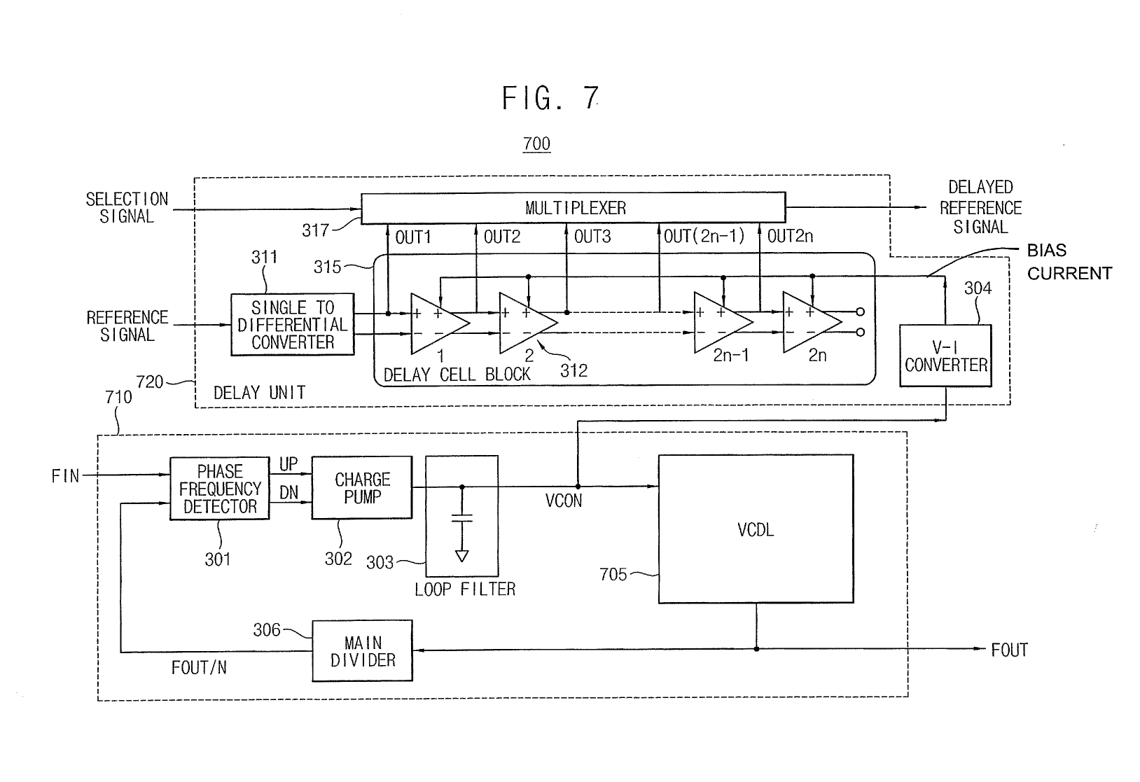

In apparatus/methods 700 of controlling a delay in FIG. 7, a PLL 710 uses a voltage controlled delay line (VCDL) 705 instead of the ring oscillator 305 illustrated in FIG. 3.

In FIG. 6 and in FIG. 7, the delay units 620 and 720 generate a bias current based on a control voltage VCON generated by the PLLs 610 and 710, and control the delay interval based on the bias current. That is, in some embodiments, the delay units 620 and 720 increase the frequency of the reference signal by decreasing the delay interval when the bias current is increased, and decrease the frequency of the reference signal by increasing the delay interval when the bias current is decreased.

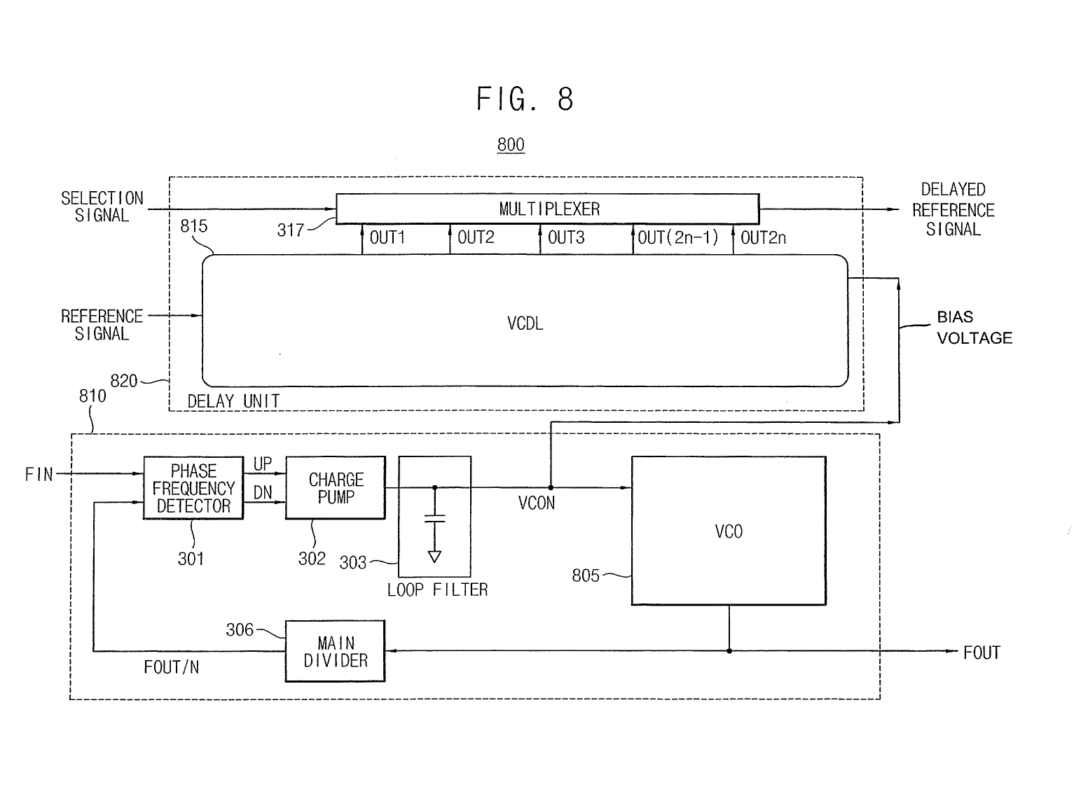

In apparatus/methods 800 of controlling a delay in FIG. 8, a PLL 810 uses a voltage controlled oscillator (VCO) 805 instead of the ring oscillator 305 illustrated in FIG. 3 and the delay unit 820 uses a voltage controlled delay line (VCDL) 815 controlled by a bias voltage whereas the delay cell block 315 is controlled by a bias current.

In FIG. 8, the delay unit 820 controls the delay interval based on a control (bias) voltage generated by the PLL 810. That is, in some embodiments, the delay unit 820 increases a frequency of the reference signal by decreasing the delay interval when the control voltage is increased, and decreases the frequency of the reference signal by increasing the delay interval when the control voltage is decreased.

Accordingly, apparatus/methods of controlling a delay according to example embodiments of the present invention can output the delayed reference signal at a desired time.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. An apparatus for controlling a delay, comprising:
a phase locked loop configured to generate an oscillation signal having a frequency substantially identical to that of a reference signal; and
a delay unit including a delay cell block configured to output delayed signals by delaying the reference signal sequentially by a uniform delay interval, the delay unit controlling the delay interval based on a frequency/phase difference between a first input signal and a second input signal of the phase locked loop and outputting one of the delayed signals as a delayed reference signal.

2. The apparatus of claim 1, wherein the delay unit is configured to decrease the delay interval when the frequency/phase of the first input signal is higher than that of the second input signal, and to increase the delay interval when the frequency/phase of the first input signal is lower than that of the second input signal.

3. The apparatus of claim 1, wherein the delay unit is configured to output the one of the delayed signals as the delayed reference signal based on a selection signal that is provided externally and/or set in advance.

4. The apparatus of claim 1, wherein the phase locked loop is configured to generate a control voltage based on the frequency/phase difference between the first input signal and the second input signal, to convert the control voltage into a bias current, to generate the oscillation signal based on the bias current, and to generate the second input signal by dividing the oscillation signal.

5. The apparatus of claim 4, wherein the phase locked loop is configured to increase the control voltage when the frequency/phase of the first input signal is higher than that of the second input signal, to increase the bias current according to the increased control voltage, and to increase a frequency of the oscillation signal based on the increased bias current.

6. The apparatus of claim 4, wherein the phase locked loop is configured to decrease the control voltage when the frequency/phase of the first input signal is lower than that of the second input signal, to decrease the bias current according to the decreased control voltage, and to decrease a frequency of the oscillation signal based on the decreased bias current.

7. The apparatus of claim 4, wherein the phase locked loop comprises:
a ring oscillator configured to control the frequency of the oscillation signal based on the bias current that is increased when the frequency/phase of the first input signal is higher than that of the second input signal or that is decreased when the frequency/phase of the first input signal is lower than that of the second input signal.

8. The apparatus of claim 7, wherein the ring oscillator is configured to increase the frequency of the oscillation output signal when the bias current is increased, and to decrease the frequency of the oscillation signal when the bias current is decreased.

9. The apparatus of claim 4, wherein the delay unit is configured to control the delay interval based on the converted bias current.

10. The apparatus of claim 9, wherein the delay unit is configured to increase the frequency of the delayed signals by decreasing the delay interval when the bias current is increased, and to decrease the frequency of the delayed signals by increasing the delay interval when the bias current is decreased.

11. The apparatus of claim 10, wherein the delay unit further includes:
a single-to-differential converter configured to convert the reference signal into differential signals; and
a multiplexer configured to select the one of the delayed signals as the delayed reference signal based on a selection signal that is provided externally and/or set in advance; and
wherein the delay cell block includes delay cells, each of the delay cells controlling the delay interval based on the increased or decreased bias current.

12. The apparatus of claim 11, wherein each of the delay cells includes:
a first p-channel transistor configured to mirror a first bias current, a source of the first p-channel transistor receiving a first reference voltage;
a second p-channel transistor configured to mirror the first bias current, a source of the second p-channel transistor receiving the first reference voltage;
a first n-channel transistor having a gate receiving a first signal of the differential signals and a drain coupled to a drain of the first p-channel transistor;
a second n-channel transistor having a gate receiving a second signal of the differential signals and a drain coupled to a drain of the second p-channel transistor; and
a third n-channel transistor configured to mirror a second bias current, a source of the third n-channel transistor receiving a second reference voltage, a drain of the third n-channel transistor being coupled to sources of the first n-channel transistor and the second n-channel transistor.

13. The apparatus of claim 1, wherein the delay unit is configured to generate the bias current based on a control voltage generated from the phase locked loop, and to control the delay interval based on the bias current.

14. The apparatus of claim 13, wherein the delay unit is configured to increase the frequency of the reference signal by decreasing the delay interval when the bias current is increased, and to decrease the frequency of the reference signal by increasing the delay interval when the bias current is decreased.

15. The apparatus of claim 1, wherein the delay unit is configured to control the delay interval based on a control voltage generated from the phase locked loop.

16. The apparatus of claim 15, wherein the delay unit is configured to increase the frequency of the delayed signals by decreasing the delay interval when the control voltage is increased, and to decrease the frequency of the delayed signals by increasing the delay interval when the control voltage is decreased.

17. The apparatus of claim 1, wherein the reference signal corresponds to a data strobe signal of a dynamic random access memory (DRAM).

18. A method of controlling a delay, comprising:
generating delayed signals by delaying a reference signal sequentially by a uniform delay interval;
controlling the delay interval based on a frequency/phase difference between a first input signal and a second input signal of a phase locked loop that outputs an oscillation signal having a frequency substantially identical to that of the reference signal; and
outputting one of the delayed signals as a delayed reference signal.

19. The method of claim 18, wherein controlling the delay interval comprises:
decreasing the delay interval when the frequency/phase of the first input signal is higher than that of the second input signal; and
increasing the delay interval when the frequency/phase of the first input signal is lower than that of the second input signal.

20. The method of claim 18, wherein outputting the one of the delayed signals as the delayed reference signal comprises:
outputting the one of the delayed signals as the delayed reference signal based on a selection signal that is provided externally and/or set in advance.

21. The method of claim 18, wherein controlling the delay interval comprises:
generating a control voltage based on the frequency/phase difference between the first input signal and the second input signal;
converting the control voltage into a bias current; and
controlling the delay interval based on the converted bias current.

22. An apparatus for controlling a delay, comprising:
a phase locked loop; and
a delay unit configured to output a delayed reference signal in response to a reference signal applied thereto, the delay unit being powered by a power supply and being biased by a bias current/voltage that is generated from the phase locked loop.

23. The apparatus of claim 22 wherein the delay unit comprises a plurality of serially connected delay stages, a respective one of which is powered by the power supply and is biased by the bias current/voltage that is generated from the phase locked loop.

24. A method of controlling a delay, comprising:
biasing a delay unit, which is configured to output a delayed reference signal in response to a reference signal applied thereto and is powered from a power supply, with a bias current/voltage that is generated from a phase locked loop.

25. A method according to claim 24 further comprising:
generating the bias current/voltage in response to a phase difference in the phase locked loop.
